(19) United States
(12) Patent Application Publication
(10) Pub. No.: US 2015/0303947 A1
(43) Pub. Date: Oct. 22, 2015

(54) Systems and Methods for Protected Portion Data Processing

(71) Applicant: LSI Corporation, San Jose, CA (US)

(72) Inventors: Shu Li, San Jose, CA (US); Shaohua Yang, San Jose, CA (US); Yu Chin Fabian Lim, San Jose, CA (US)

(73) Assignee: LSI Corportaion, San Jose, CA (US)

(21) Appl. No.: 14/261,324

(22) Filed: Apr. 24, 2014

Related U.S. Application Data
(60) Provisional application No. 61/981,543, filed on Apr. 18, 2014.

(51) Int. Cl. H03M 13/29; G11B 20/18; G06F 11/10

(52) U.S. Cl. CPC H03M 13/2906; G06F 11/1076; G11B 20/1833

(57) ABSTRACT

The present inventions are related to systems and methods for data processing, and more particularly to systems and methods for protecting portions of data sets during data processing.

### CROSS REFERENCE TO RELATED APPLICATIONS

The present application claims priority to (is a non-provisional of) U.S. Pat. App. No. 61/981,543, entitled “Systems and Methods for Protected Portion Data Processing”, and filed Apr. 18, 2014 by Li et al. The entirety of the aforementioned provisional patent application is incorporated herein by reference for all purposes.

### FIELD OF THE INVENTION

The present inventions are related to systems and methods for data processing, and more particularly to systems and methods for protecting portions of data sets during data processing.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. In some cases, data decoding fails to properly decode the data.

Hence, for at least the aforementioned reasons, there exists a need in the art for advanced systems and methods for data processing.

### BRIEF SUMMARY

The present inventions are related to systems and methods for data processing, and more particularly to systems and methods for protecting portions of data sets during data processing.

Various embodiments of the present invention provide data processing systems that include a data encoder circuit. The data encoder circuit is operable to: receive a data set; augment the data set to include a first protected parity portion corresponding to a first codeword to yield an augmented data set; apply a first encoding algorithm to the augmented data set to yield a second codeword; and apply a second encoding algorithm to a portion of the second codeword to yield second protected parity portion.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a data processing circuit including protected portion encoding and decoding circuitry in accordance with one or more embodiments of the present invention;

FIG. 2 depicts a data transmission system including protected portion encoding and decoding circuitry in accordance with various embodiments of the present invention;

FIGS. 3a-3e graphically depict a process for protected portion encoding in accordance with some embodiments of the present invention;

FIG. 4 shows a data encoding circuit in accordance with various embodiments of the present invention;

FIGS. 5a-5b show a data processing system including a protected portion LDPC decoding circuit in accordance with various embodiments of the present invention;

FIG. 6 is a flow diagram showing a method for protected portion encoding in accordance with various embodiments of the present invention;

FIG. 7 is a flow diagram showing a method for protected portion decoding in accordance with some embodiments of the present invention;

FIGS. 8a-8d graphically depict a process for protected portion encoding transferred using puncture in accordance with some embodiments of the present invention;

FIG. 9 shows a data encoding circuit transporting protected portion encoding via puncture in accordance with various embodiments of the present invention;

FIG. 10 shows a protected portion data decoding circuit in accordance with various embodiments of the present invention;

FIG. 11 is a flow diagram showing a method for puncture transported protected portion encoding in accordance with various embodiments of the present invention; and

FIG. 12 is a flow diagram showing a method for puncture transported protected portion decoding in accordance with some embodiments of the present invention.

### DETAILED DESCRIPTION OF THE INVENTION

The present inventions are related to systems and methods for data processing, and more particularly to systems and methods for protecting portions of data sets during data processing.

Various embodiments of the present invention provide data processing systems that include a data encoder circuit. The data encoder circuit is operable to: receive a data set; augment the data set to include a first protected parity portion corresponding to a first codeword to yield an augmented data set; apply a first encoding algorithm to the augmented data set to yield a second codeword; and apply a second encoding algorithm to a portion of the second codeword to yield second protected parity portion. In some instances of the aforementioned embodiments, the data processing system is implemented as part of an integrated circuit. In various instances of the aforementioned embodiments, the data processing system is part of a data storage device including a storage medium, and the data set is derived from the storage medium. In other instances of the aforementioned embodiments, the data processing system is part of a data storage device including a storage medium, and the data set is derived from the storage medium.

In some instances of the aforementioned embodiments, the data set is a first data set and the augmented data set is a second augmented data set. In such instances, the encoder circuit is further operable to: receive a second data set; augment the second data set to include the second protected parity portion corresponding to the second codeword to yield a second augmented data set; apply the first encoding algorithm to the second augmented data set to yield a third codeword; and apply the second encoding algorithm to a portion of the third codeword to yield third protected parity portion.

In various embodiments of the present invention, the first encoding algorithm is a low density parity check encoding algorithm. In some embodiments of the present invention, the second encoding algorithm is an algebraic encoding algorithm. In one or more embodiments of the present invention, the data processing system further includes a data decoding circuit operable to: apply a first data decoding algorithm to the second codeword to yield a user data portion and the first protected parity portion; collect data from a user data portion of the first codeword corresponding to the first protected parity portion; apply a second data decoding algorithm to a combination of the user data portion for the first codeword and the first protected parity portion to yield a corrected bit output; and correct a bit in the user data portion for the first codeword based upon the corrected bit pattern.

In one particular embodiment of the present invention, the second codeword includes a second user data portion and a second protected parity portion, the first codeword includes a first user data portion and a first protected parity portion, and the first user data portion and the second user data portion are the same length. In one particular embodiment of the present invention, the second codeword includes a second user data portion and a second protected parity portion, the first codeword includes a first user data portion and a first protected parity portion, and the first user data portion and the second user data portion are different lengths. In yet other particular embodiments of the present invention, the second codeword includes a second user data portion and a second protected parity portion, the first codeword includes a first user data portion and a first protected parity portion, and the first protected parity portion and the second protected parity portion are the same length. In further embodiments of the present invention, the second codeword includes a second user data portion and a second protected parity portion, the first codeword includes a first user data portion and a first protected parity portion, and the first protected parity portion and the second protected parity portion are different lengths.

Other embodiments of the present invention provide methods for data processing. The methods include: receiving a data set; augmenting the data set to include a first protected parity portion corresponding to a first codeword to yield an augmented data set; applying a first encoding algorithm to the augmented data set to yield a second codeword; and applying a second encoding algorithm to a portion of the second codeword to yield second protected parity portion. In some embodiments of the present invention, the data set is a first data set and the augmented data set is a second augmented data set. In such instances, the methods include: receiving a second data set; augmenting the second data set to include the second protected parity portion corresponding to the second codeword to yield a second augmented data set; applying the first encoding algorithm to the second augmented data set to yield a third codeword; and applying the second encoding algorithm to a portion of the third codeword to yield third protected parity portion. In some cases, the first encoding algorithm is a low density parity check encoding algorithm. In various cases, the second encoding algorithm is not a low density parity check algorithm.

In one or more instances of the aforementioned embodiments, the methods further include: applying a first data decoding algorithm to the second codeword to yield a user data portion and the first protected parity portion; collecting data from a user data portion of the first codeword corresponding to the first protected parity portion; applying a second data decoding algorithm to a combination of the user data portion for the first codeword and the first protected parity portion to yield a corrected bit output; and correcting a bit in the user data portion for the first codeword based upon the corrected bit pattern. In particular instances of the aforementioned embodiments, the second protected parity portion is encoded data corresponding to problematic user data in the first codeword.

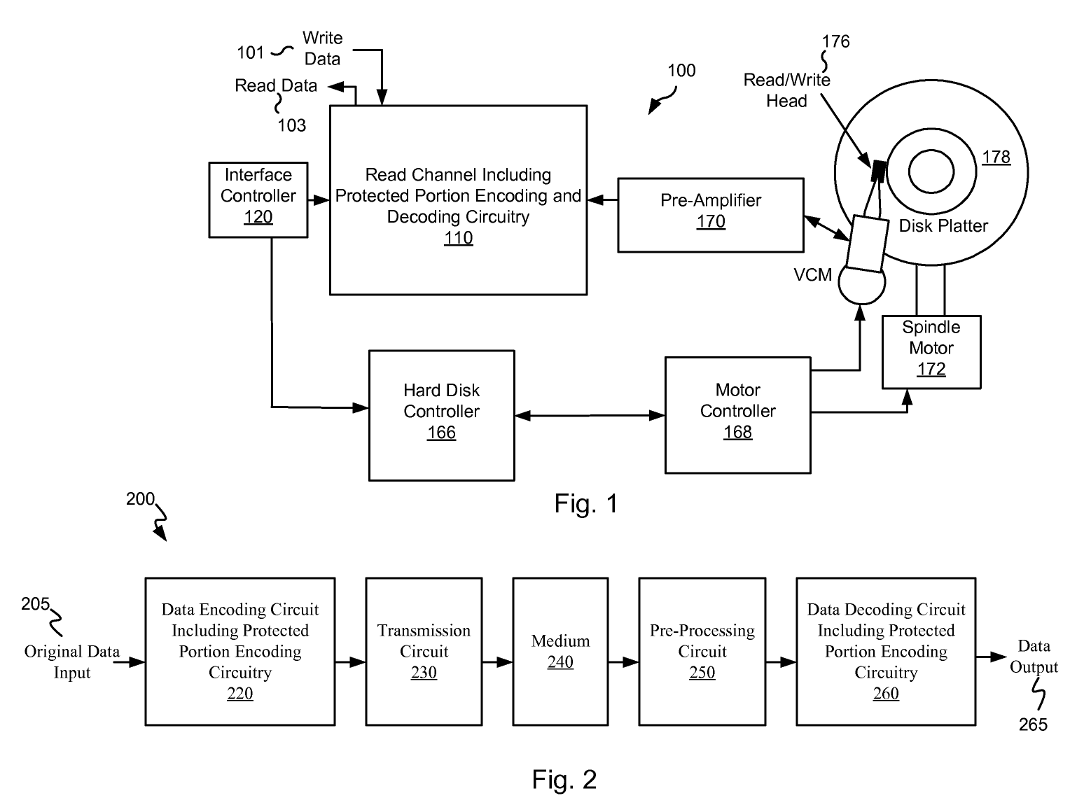

Turning to FIG. 1, a storage system 100 including a read channel circuit 110 that includes protected portion encoding and decoding circuitry in accordance with one or more embodiments. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head assembly 176. Interface controller 120 controls addressing and timing of data to/from disk platter 178. The data on disk platter 178 consists of groups of magnetic signals that may be detected by read/write head assembly 176 when the assembly is properly positioned over disk platter 178. In one embodiment, disk platter 178 includes magnetic signals recorded in accordance with a perpendicular recording scheme. For example, the magnetic signals may be recorded as either longitudinal or perpendicular recorded signals.

In a typical read operation, read/write head assembly 176 is accurately positioned by motor controller 168 over a desired data track on disk platter 178. The appropriate data track is defined by an address received via interface controller 120. Motor controller 168 both positions read/write head assembly 176 in relation to disk platter 178 and drives spindle motor 172 by moving read/write head assembly to the proper data track on disk platter 178 under the direction of hard disk controller 166. Spindle motor 172 spins disk platter 178 at a determined spin rate (RPMs). Once read/write head assembly 176 is positioned adjacent the proper data track, magnetic signals representing data on disk platter 178 are sensed by read/write head assembly 176 as disk platter 178 is rotated by spindle motor 172. The sensed magnetic signals are provided as a continuous, minute analog signal representative of the magnetic data on disk platter 178. This minute analog signal is transferred from read/write head assembly 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. The read data is provided as read data 103. A write operation is substantially the opposite of the preceding read operation with write data 101 being provided to read channel circuit 110. This data is then encoded and written to disk platter 178.

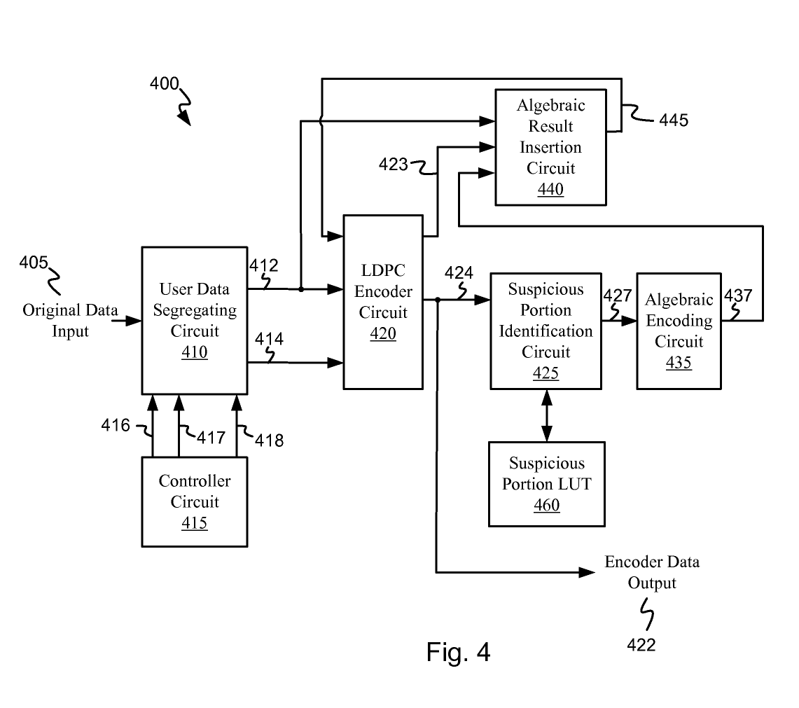

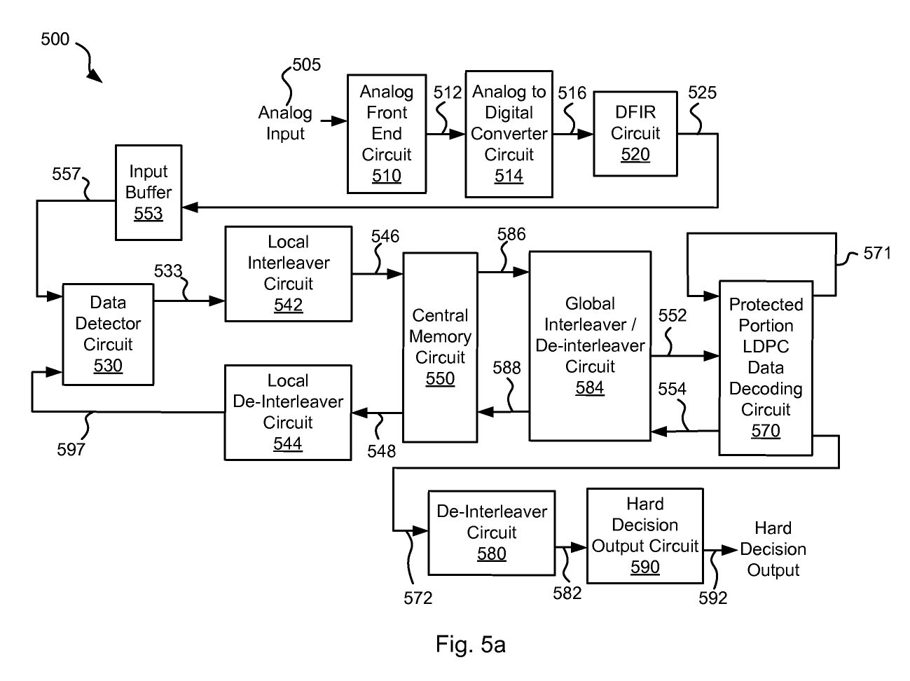

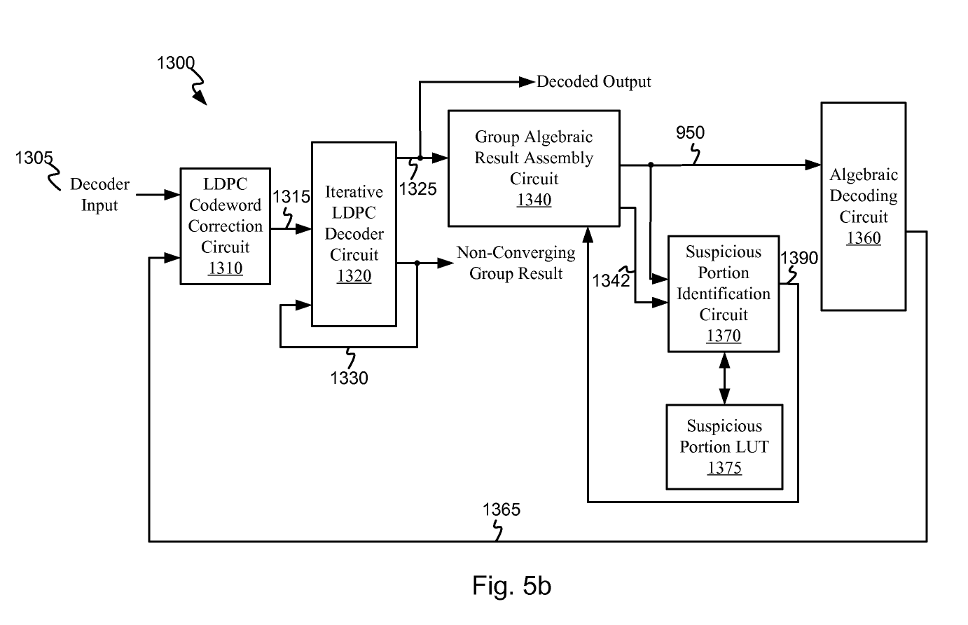

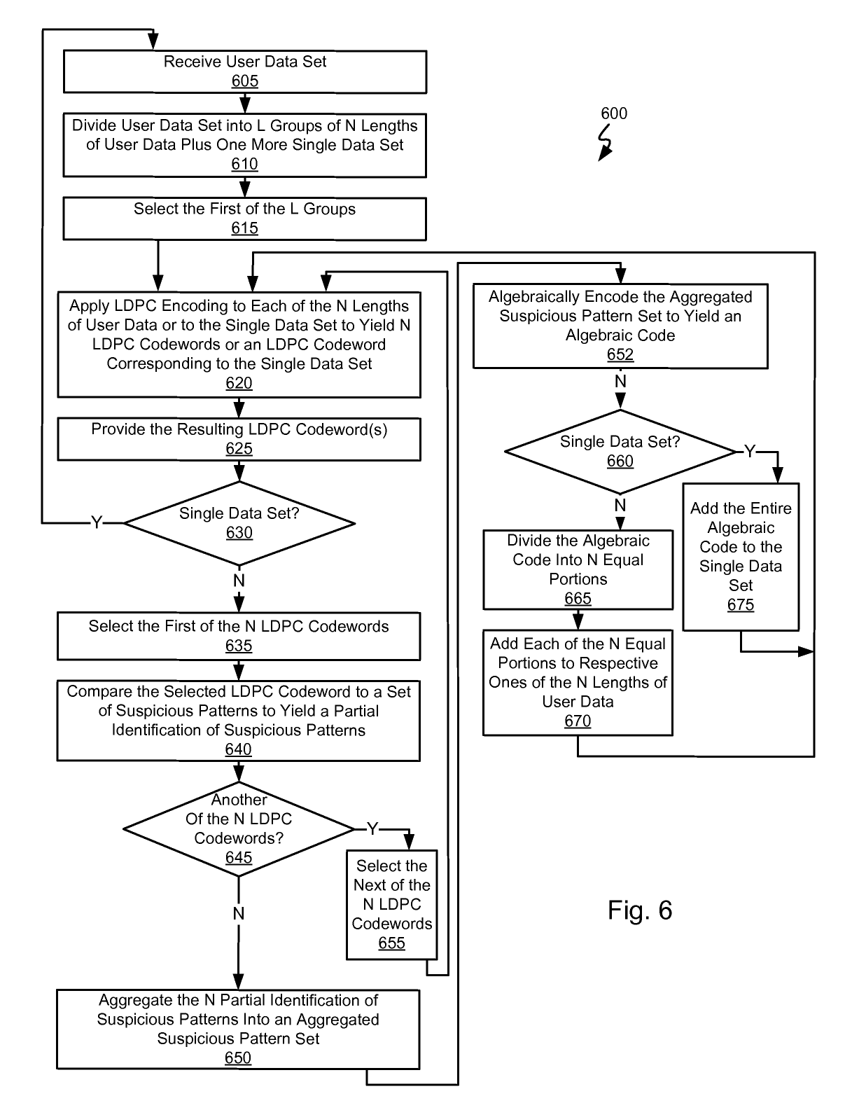

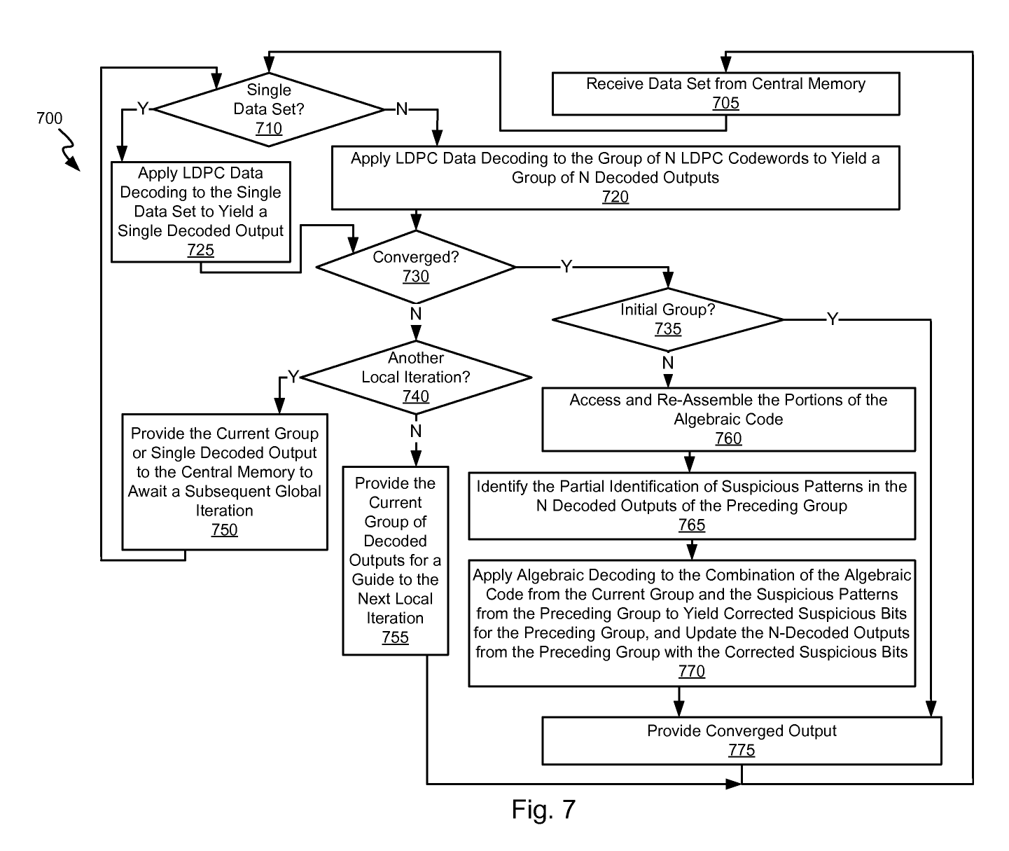

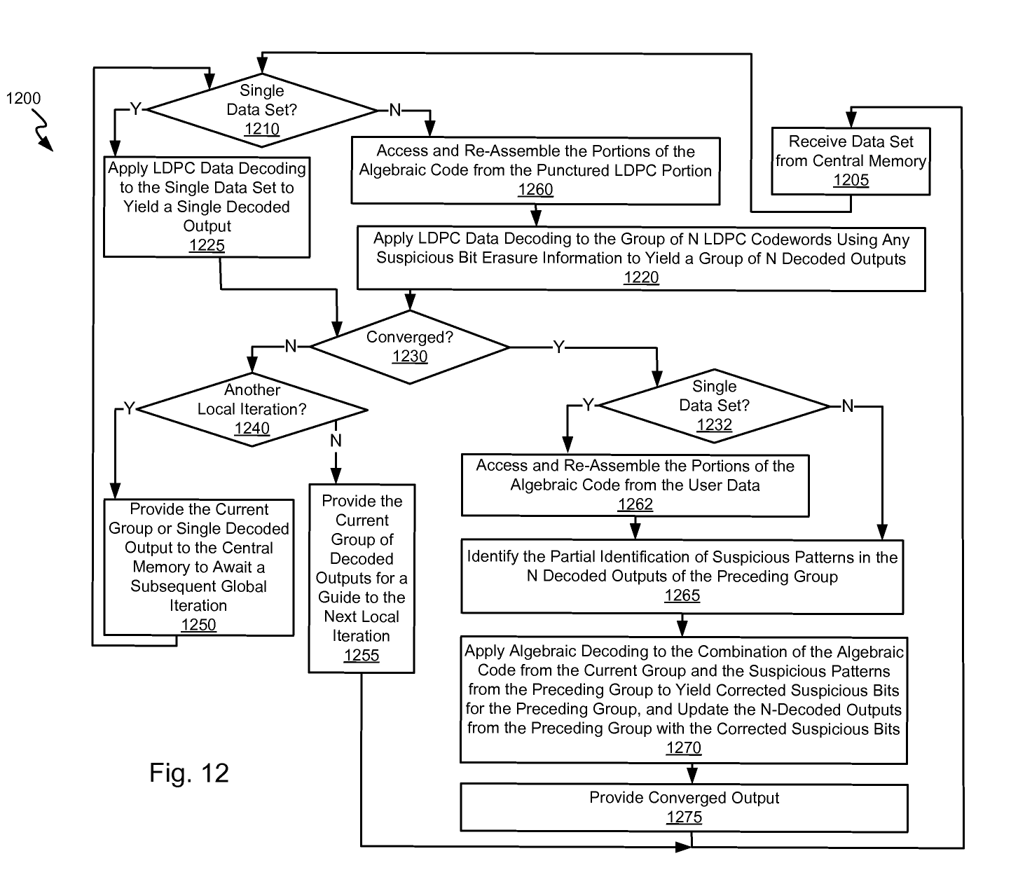

Writing data to disk platter 178 includes applying protected portion encoding in addition to a broader encoding to yield codewords that are stored. In one embodiment, the encoding process includes encoding a data set using a first encoding algorithm to yield an encoded output. This is the encoded output that is stored to disk platter 178. In addition, the encoding process includes: identifying any suspicious bit patterns in the encoded output, grouping the identified suspicious bit patterns, and applying a second encoding algorithm to the group of identified suspicious bits to yield a protected portion output. The added encoding bits of the protected portion output are incorporated into the next data set to be encoded, and the first encoding algorithm is applied to the data set to yield another encoded output that is stored to disk platter 178. Such encoding may be done, for example, using the circuit of FIG. 4 and/or using the method of FIG. 6 or FIG. 11. The decoding process is essentially the reverse of the encoding process with data from a subsequently decoded codeword being used to correct the identified suspicious bit patterns in the previous codeword that failed to converge. Such decoding may be done, for example, using the circuit of FIGS. 5a-5b and/or using the method of FIG. 7 or FIG. 12.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

Turning to FIG. 2, a data transmission system 200 including protected portion encoding and decoding circuitry is shown in accordance with various embodiments of the present invention. Data transmission system 200 includes a data encoding circuit 220 including protected portion encoding circuitry that applies encoding to an original data input 205 and provides an encoded output. The encoding process includes encoding a data set using a first encoding algorithm to yield an encoded output. This is the encoded output is provided to a transmission circuit 230. In addition, the encoding process includes: identifying any suspicious bit patterns in the encoded output, grouping the identified suspicious bit patterns, and applying a second encoding algorithm to the group of identified suspicious bits to yield a protected portion output. The added encoding bits of the protected portion output are incorporated into the next data set to be encoded, and the first encoding algorithm is applied to the data set to yield another encoded output that is provided to transmission circuit 230. Such encoding may be done, for example, using the circuit of FIG. 4 and/or using the method of FIG. 6 or FIG. 11.

Original data input 205 may be any set of input data. For example, where data processing system 200 is a hard disk drive, original input 205 may be a data set that is destined for storage on a storage medium. In such cases, a medium 240 of data processing system 200 is a storage medium. As another example, where data processing system 200 is a communication system, original input 205 may be a data set that is destined to be transferred to a receiver via a transfer medium. Such transfer mediums may be, but are not limited to, wired or wireless transfer mediums. In such cases, a medium 240 of data processing system 200 is a transfer medium.

Transmission circuit 230 may be any circuit known in the art that is capable of transferring the received codeword 225 via medium 240. Thus, for example, where data processing circuit 200 is part of a hard disk drive, transmission circuit 230 may include a read/write head assembly that converts an electrical signal into a series of magnetic signals appropriate for writing to a storage medium. Alternatively, where data processing circuit 200 is part of a wireless communication system, transmission circuit 230 may include a wireless transmitter that converts an electrical signal into a radio frequency signal appropriate for transmission via a wireless transmission medium. Transmission circuit 230 provides a transmission output to medium 240. Medium 240 provides a transmitted input that is the transmission output augmented with one or more errors introduced by the transference across medium 240.

Data transmission circuit 200 includes a pre-processing circuit 250 that applies one or more analog functions to the transmitted input. Such analog functions may include, but are not limited to, amplification and filtering. Based upon the disclosure provided herein, one of ordinary skill in the art will recognize a variety of pre-processing circuitry that may be used in relation to different embodiments of the present invention. Pre-processing circuit 250 provides a pre-processed output to a data decoding circuit 260 that includes protected portion encoding circuitry. The decoding process is essentially the reverse of the encoding process with data from a subsequently decoded codeword being used to correct the identified suspicious bit patterns in the previous codeword that failed to converge. Such decoding may be done, for example, using the circuit of FIGS. 5a-5b and/or using the method of FIG. 7 or FIG. 12. The result of the decoding process is provided as a data output 265.

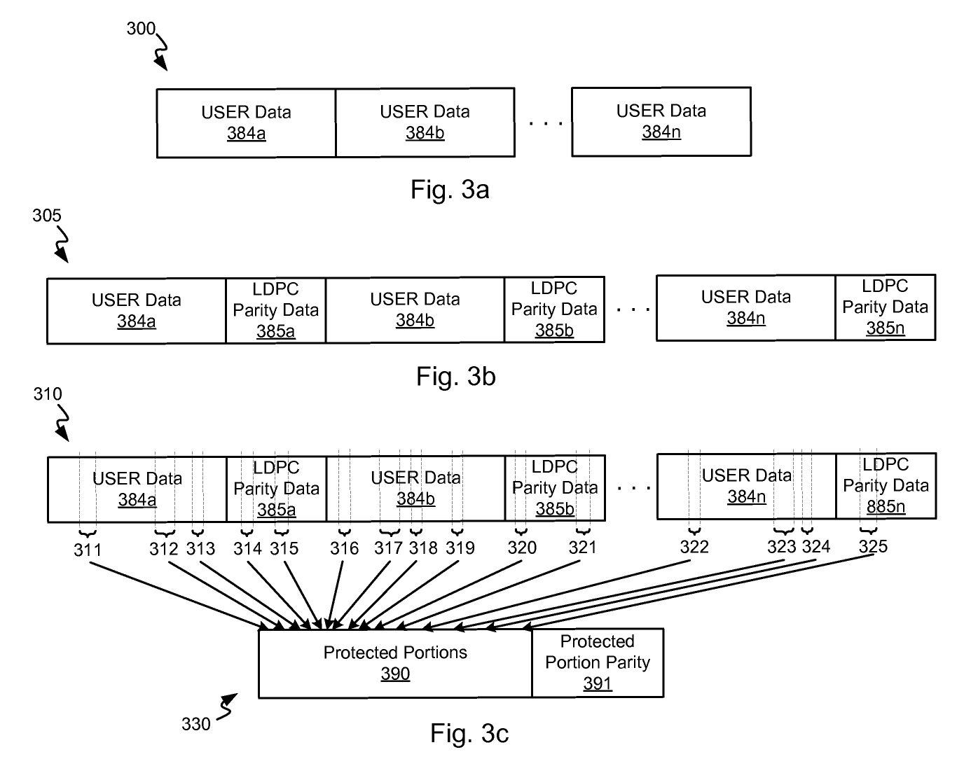

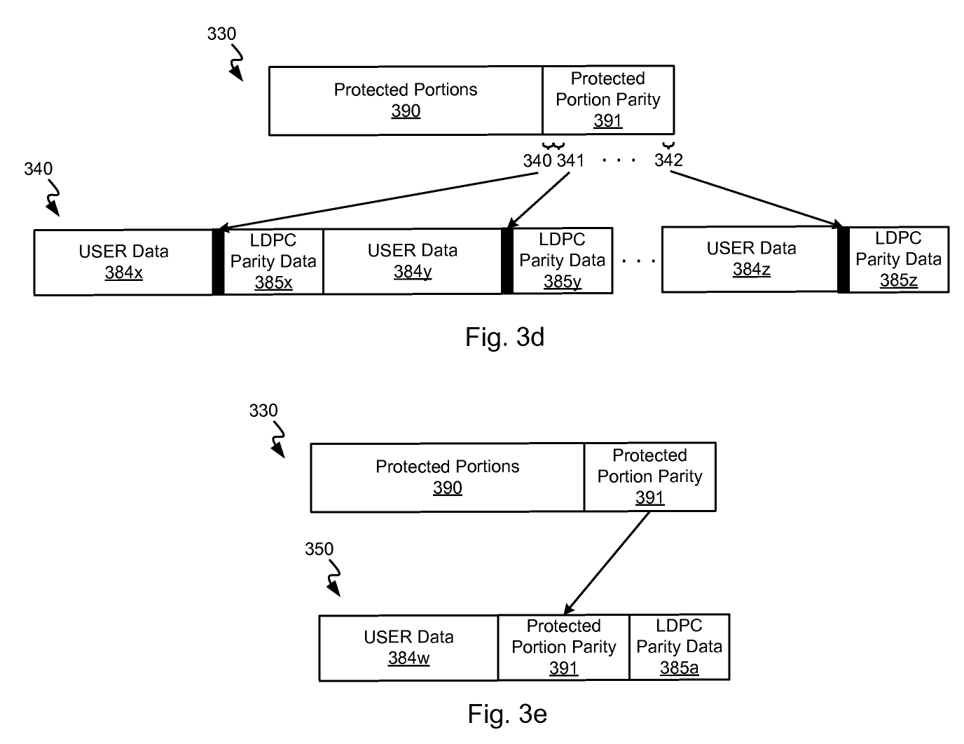

Turning to FIGS. 3a-3e, a process for protected portion encoding is graphically displayed in accordance with some embodiments of the present invention. Turning to FIG. 3a, a graphical representation 300 shows a data set divided into a number of user data portions 384a, 384b, 384n. In some embodiments of the present invention, the data set is divided into L-groups plus one single set, where each of the L-groups includes N-user data portions. In such an embodiment, graphical representation 300 represents one of the L-groups of N-user data portions.

Turning to FIG. 3b, a graphical representation 305 shows a number of LDPC codewords that result from applying an LDPC encoding to each of user data portions 384a, 384b, 384n for a given one of the L-groups. The codewords each include a user data portion and corresponding LDPC parity data. In particular, one LDPC codeword includes user data portion 384a and LDPC parity data 385a, another LDPC codeword includes user data portion 384b and LDPC parity data 385b, and another LDPC codeword includes user data portion 384n and LDPC parity data 385n.

Turning to FIG. 3c, after the encoding discussed in relation to FIG. 3b, suspicious bit patterns are identified in the resulting N-LDPC codewords as shown in a graphical representation 310. In particular, identified suspicious bit patterns 311, 312, 313, 314, 315, 316, 317, 318, 319, 320, 321, 322, 323, 324, 325 are identified. The suspicious bit patterns are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns. In one particular embodiment of the present invention, the suspicious bit patterns are stored to a memory where the can be accessed for comparison with the group of N-LDPC codewords for identification.

Identified suspicious bit patterns 311, 312, 313, 314, 315, 316, 317, 318, 319, 320, 321, 322, 323, 324, 325 are aggregated to yield a protected portions segment 390. A secondary encoding is applied to protected portions segment 390 to yield a protected portion parity 391. Of note, identified suspicious bit patterns 311, 312, 313, 314, 315, 316, 317, 318, 319, 320, 321, 322, 323, 324, 325 may come from either user data portions, LDPC parity bits, or a combination of both. Further, more suspicious bit patterns may be derived from one of the N-LDPC codewords than from another of the N-LDPC codewords. Any encoding algorithm known in the art that is capable of generating encoded data based upon a data input may be used to apply the secondary encoding. In some embodiments of the present invention, the secondary encoding is a non-LDPC encoding. In particular embodiments of the present invention, the secondary encoding is an algebraic encoding. Based upon the disclosure provided herein, one of ordinary skill in the art will recognize a variety of encoding algorithms that may be used to perform the secondary encoding.

Protected portion parity 391 is incorporated into the next group of the L-groups. Thus, the first of the L-groups does not receive any protected parity portion 391. The protected parity portion 391 generated based upon suspicious bit patterns in the first if the L-groups is incorporated into the second of the L-groups. Similarly, the protected parity portion 391 generated based upon suspicious bit patterns in the second if the L-groups is incorporated into the third of the L-groups. This continues until the one single set receives the protected parity portion 391 for the last of the L-groups. Identification of suspicious bit patterns is not performed on the one single set.

Turning to FIG. 3d, a graphical representation 340 shows where each of the N-user data portions for the group is augmented to include 1/n^{th} (represented as respective parity portions 340, 341, 342) of the protected parity portion 391 from the preceding one of the L-groups. As shown, parity portions 340, 341, 342 are appended to the end of the respective N-user data portions (i.e., parity portion 340 is appended to the end of user data 384x; parity portion 341 is appended to the end of user data 384y; and parity portion 342 is appended to the end of the user data 384z). LDPC encoding is then applied to each of the N-augmented sets of user data to yield corresponding LDPC parity bits. In particular, LDPC encoding is applied to the combination of parity portion 340 and user data 384x to yield LDPC parity data 385x; LDPC encoding is applied to the combination of parity portion 341 and user data 384y to yield LDPC parity data 385y; and LDPC encoding is applied to the combination of parity portion 342 and user data 384z to yield LDPC parity data 385z. Turning to FIG. 3e, a graphical representation 350 shows the situation where the one single set that follows the L-groups is appended to include all of the protected parity portion 391 from the last of the L-groups. LDPC encoding is applied to the combination of protected portion parity 391 and us data 384w yield LDPC a single LDPC codeword.

Turning to FIG. 4, a data encoding circuit 400 is shown in accordance with various embodiments of the present invention. Data encoding circuit 400 includes a user data segregating circuit 410 that receives an original data input 405, and segregates the received data into L-groups of N-lengths of data plus one more single data set based upon inputs 416, 417, 418 from a controller circuit 415. Controller circuit 415 is operable to: provide a count value as input 416 for the length of each of the N-lengths of data in the first L-group; provide a count value as input 417 for the length of each of the N-lengths of data in the subsequent L-groups; and provide a count value as input 418 for the length of the single set of data. In some cases, the N-lengths of data are equal lengths. In other cases, the lengths are different. In one particular embodiment of the present invention, in the first of the L-groups the N-lengths is a length that when added to generated LDPC parity yields a desired LDPC codeword length. This length is indicated by input 416. In the other of L-groups, the N-lengths in each are shortened such that they are of a length that when added to both generated LDPC parity and 1/n^{th} of a protected portions segment yields the desired LDPC codeword length. This length is indicated by input 417. The length of the single data set is such that when added to generated LDPC parity and the protected portions segment yields the desired LDPC codeword length. The length is indicated by input 418. Such a variable length segmentation results in codewords (user data plus LDPC encoding, and in some cases, the protected portions segment) are the same length.

User data segregating circuit 410 provides the L-groups of N-lengths of data plus one more single data set as a data output 412. A status output 414 indicates whether the data provided as data output 412 is in the first of the L-groups, the other of the L-groups, or the single data set. Data output 412 is provided to both an LDPC encoder circuit 420 and an algebraic result insertion circuit 440. When status output 414 indicated that data output 412 is the first of the L-groups of N-lengths, LDPC encoder circuit 420 applies a low density parity check encoding algorithm to each of the N-lengths of data in the first of the L-groups. Application of the a low density parity check encoding algorithm results in N-LDPC codewords 424, with each of the N-LDPC codewords 424 corresponding to a respective one of the N-lengths of data received as data output 412.

The N-LDPC codewords 424 are provided as an encoder data output 422. In addition, the N-LDPC codewords 424 are provided to a suspicious portion identification circuit 425. Suspicious portion identification circuit 425 compares the N-LDPC codewords 424 to a set of suspicious patterns to yield a partial identification of suspicious patterns maintained in a suspicious portion look up table 460. The result of the comparison of the N-LDPC codewords 424 to the set of suspicious patterns is provided as an aggregated suspicious portion output 427. Aggregated suspicious portion output 427 includes suspicious portions across an entire L-group. An example of an aggregated suspicious portion output 427 (shown as protected portions 390) is shown in FIG. 3c where a number of identified suspicious bit patterns 311, 312, 313, 314, 315, 316, 317, 318, 319, 320, 321, 322, 323, 324, 325 are aggregated.

The suspicious patterns maintained in suspicious portion look up table 460 are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns.

Aggregated suspicious portion output 427 is provided to an algebraic encoding circuit 435 that applies an algebraic encoding algorithm to the received input to yield protected portion parity data 437. FIG. 3c shows an example of encoding the aggregated suspicious pattern set (shown as protected portions 390) is encoded to yield protected portion parity data 437 (shown as protected portion parity 391). The algebraic encoding may be any encoding known in the art. In various embodiments of the present invention, the algebraic encoding algorithm that is applied is specifically chosen to be different from the LDPC encoding algorithm applied by LDPC encoder circuit 420. In some embodiments of the present invention, the algebraic encoding is specifically designed to address the error floor of the LDPC encoding algorithm by protecting suspicious bit patterns likely to negatively impact the error floor of the LDPC encoding algorithm, while leaving the waterfall region of the LDPC encoding algorithm largely unchanged. In one particular embodiment of the present invention, the algebraic encoding algorithm is a weak BCH encoding algorithm as is known in the art. In another particular embodiment of the present invention, the algebraic encoding algorithm is a strong BCH encoding algorithm as is known in the art.

Protected portion parity data 437 is provided to an algebraic result insertion circuit 440. Algebraic result insertion circuit 440 receives a status indicator 423 from LDPC encoder circuit 420 indicating whether the next data set to be encoded is one of the L-groups of data or the single data set. Where status indicator 423 indicates that the next data set to be encoded is one of the L-groups of data, algebraic result insertion circuit 440 divides protected portion parity data 437 into N-equal parts, and the N-equal parts are added to respective ones of the N-equal parts of the next L-group of data received as data output 412. The result is provided as an augmented data set 445 that is provided back to LDPC encoder circuit 420. In turn, LDPC encoder circuit 420 applies the low density parity check encoding algorithm to each of the N-lengths of data (i.e., the original data plus 1/n^{th} of the Protected portion parity data 437) to yield N-LDPC codewords 424, with each of the N-LDPC codewords 424 corresponding to a respective one of the N-lengths of the augmented data received as augmented data set 445. Alternatively, where status indicator 423 indicates that the next data set to be encoded is the single data set, algebraic result insertion circuit 440 adds the entire protected portion parity data 437 to the single data set received as data output 412. The result is provided as an augmented data set 445 that is provided back to LDPC encoder circuit 420. In turn, LDPC encoder circuit 420 applies the low density parity check encoding algorithm to the augmented single data set (i.e., the original single set of data plus the Protected portion parity data 437) to yield N-LDPC codewords 424.

Turning to FIG. 5a, a data processing system 500 including a protected portion LDPC decoding circuit 570 is shown in accordance with various embodiments of the present invention. Data processing system 500 includes an analog front end circuit 510 that receives an analog signal 505. Analog front end circuit 510 processes analog signal 505 and provides a processed analog signal 512 to an analog to digital converter circuit 514. Analog front end circuit 510 may include, but is not limited to, an analog filter and an amplifier circuit as are known in the art. Based upon the disclosure provided herein, one of ordinary skill in the art will recognize a variety of circuitry that may be included as part of analog front end circuit 510. Analog signal 505 represents protected portion codewords that may be similar to that discussed above in relation to FIG. 3b, 3d or 3e. In some cases, where data processing circuit 500 is implemented as part of a storage device, analog signal 505 is derived from a read/write head assembly (not shown) that is disposed in relation to a storage medium (not shown). In other cases, analog signal 505 is derived from a receiver circuit (not shown) that is operable to receive a signal from a transmission medium (not shown). The transmission medium may be wired or wireless. Based upon the disclosure provided herein, one of ordinary skill in the art will recognize a variety of source from which analog input 505 may be derived.

Analog to digital converter circuit 514 converts processed analog signal 512 into a corresponding series of digital samples 516. Analog to digital converter circuit 514 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 516 are provided to an equalizer circuit 520. Equalizer circuit 520 applies an equalization algorithm to digital samples 516 to yield an equalized output 525. In some embodiments of the present invention, equalizer circuit 520 is a digital finite impulse response filter (DFIR) circuit as are known in the art. It may be possible that equalized output 525 may be received directly from a storage device in, for example, a solid state storage system. In such cases, analog front end circuit 510, analog to digital converter circuit 514 and equalizer circuit 520 may be eliminated where the data is received as a digital data input. Equalized output 525 is stored to an input buffer 553 that includes sufficient memory to maintain one or more codewords until processing of that codeword is completed through a data detector circuit 530 and a protected portion LDPC data decoding circuit 570 including, where warranted, multiple global iterations (passes through both data detector circuit 530 and protected portion LDPC data decoding circuit 570) and/or local iterations (passes through protected portion LDPC data decoding circuit 570 during a given global iteration). An output 557 is provided to data detector circuit 530.

Data detector circuit 530 may be a single data detector circuit or may be two or more data detector circuits operating in parallel on different codewords. Whether it is a single data detector circuit or a number of data detector circuits operating in parallel, data detector circuit 530 is operable to apply a data detection algorithm to a received codeword or data set. In some embodiments of the present invention, data detector circuit 530 is a Viterbi algorithm data detector circuit as are known in the art. In other embodiments of the present invention, data detector circuit 530 is a maximum a posteriori data detector circuit as are known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention. In some cases, one data detector circuit included in data detector circuit 530 is used to apply the data detection algorithm to the received codeword for a first global iteration applied to the received codeword, and another data detector circuit included in data detector circuit 530 is operable apply the data detection algorithm to the received codeword guided by a decoded output accessed from a central memory circuit 550 on subsequent global iterations.

Upon completion of application of the data detection algorithm to the received codewords on the first global iteration, data detector circuit 530 provides a detector output 533. Each instance of detector output 533 corresponds to a respective one of the data sets received as analog input 505.

Detector output 533 includes soft data. As used herein, the phrase “soft data” is used in its broadest sense to mean reliability data with each instance of the reliability data indicating a likelihood that a corresponding bit position or group of bit positions has been correctly detected. In some embodiments of the present invention, the soft data or reliability data is log likelihood ratio data as is known in the art. In cases where a higher value of soft data indicates a greater likelihood that a corresponding bit or symbol of the hybrid layer codeword has been correctly determined, setting the soft data to a maximum value makes it very unlikely that the corresponding bit will be modified during subsequent decoding or detection processes. As such, the bit or symbol is effectively frozen. Similarly, in cases where a lower value of soft data indicates a greater likelihood that a corresponding bit or symbol of the codeword has been correctly determined, setting the soft data to a minimum value makes it very unlikely that the corresponding bit will be modified during subsequent decoding or detection processes. Detected output 533 is provided to a local interleaver circuit 542. Local interleaver circuit 542 is operable to shuffle sub-portions (i.e., local chunks) of the data set included as detected output and provides an interleaved codeword 546 that is stored to central memory circuit 550. Interleaver circuit 542 may be any circuit known in the art that is capable of shuffling data sets to yield a re-arranged data set. Interleaved codeword 546 is stored to central memory circuit 550.

Once protected portion LDPC data decoding circuit 570 is available, a previously stored interleaved codeword 546 is accessed from central memory circuit 550 as a stored codeword 586 and globally interleaved by a global interleaver/de-interleaver circuit 584. Global interleaver/De-interleaver circuit 584 may be any circuit known in the art that is capable of globally rearranging codewords. Global interleaver/De-interleaver circuit 584 provides a decoder input 552 into hybrid layer data decoding circuit 570. Decoder input 552 may be protected portion codewords similar to that discussed above in relation to FIG. 3b, 3d or 3e. The data decoding algorithm applied by protected portion LDPC data decoding circuit 570 is designed to reverse the encoding described above in relation to FIG. 4. Protected portion LDPC data decoding circuit 570 applies the data decode algorithm to decoder input 552 to yield a decoded output 571.

Where decoded output 571 converged (i.e., all errors are corrected), a converged output 572 is provided to a de-interleaver circuit 580. De-interleaver circuit 580 rearranges the data to reverse both the global and local interleaving applied to the data to yield a de-interleaved output 582. De-interleaved output 582 is provided to a hard decision output circuit 590. Hard decision output circuit 590 is operable to re-order data sets that may complete out of order back into their original order. The originally ordered data sets are then provided as a hard decision output 592.

Alternatively, where decoded output 571 failed to converge (i.e., all errors are not corrected) and another local iteration is allowed, decoded output 571 is used to guide a subsequent local iteration of the data decoding algorithm by protected portion LDPC decoding circuit 570. As yet another alternative, where decoded output 571 failed to converge (i.e., all errors are not corrected), a local iteration is not allowed, and another global iteration is allowed, decoded output 571 is provided as a decoded output 554 back to central memory circuit 550 where it is stored awaiting another global iteration through a data detector circuit included in data detector circuit 530. Prior to storage of decoded output 554 to central memory circuit 550, decoded output 554 is globally de-interleaved to yield a globally de-interleaved output 588 that is stored to central memory circuit 550. The global de-interleaving reverses the global interleaving earlier applied to stored codeword 586 to yield decoder input 552. When a data detector circuit included in data detector circuit 530 becomes available, a previously stored de-interleaved output 588 accessed from central memory circuit 550 and locally de-interleaved by a de-interleaver circuit 544. De-interleaver circuit 544 re-arranges decoder output 548 to reverse the shuffling originally performed by interleaver circuit 542. A resulting de-interleaved output 597 is provided to data detector circuit 530 where it is used to guide subsequent detection of a corresponding data set previously received as equalized output 525.

Turning to FIG. 5b, one implementation of a protected portion data decoding circuit 1300 is shown in accordance with some embodiments of the present invention. Protected portion data decoding circuit 1300 may be use in place of protected portion data decoding circuit 570 discussed above in relation to FIG. 5a. Protected portion data decoding circuit 1300 includes an LDPC codeword correction circuit 1310 receives a group of codewords as a decoder input 1305 to be decoded along with corrected suspicious bits 1365. LDPC codeword correction circuit 1310 overwrites suspicious bits in decoded input 1305 where corrected suspicious bits 1365 have been generated. No corrected suspicious bits 1365 are available for the initial group of decoder input.

LDPC codeword correction circuit 1310 provides a modified codeword 1315 to an iterative LDPC decoder circuit 1320 applies a applies a low density parity check decoding algorithm (i.e., the reverse of the low density parity check encoding described above in relation to FIG. 4) to yield a decoding result. Where the decoding result converges (i.e., all errors are corrected), the decoding result is provided as a decoded output 1325. Alternatively, where the decoding result fails to converge (i.e., not all errors are corrected), the decoding result is provided as a non-converging group result 1330 that may be fed back to guide later local iterations of iterative LDPC decoder circuit 1320.

In addition, decoded output 1325 is provided to a group algebraic result assembly circuit 1340. Group algebraic result assembly circuit 1340 accesses the portions of the algebraic code (i.e., the protected portions) are accessed from the resulting decoded output and assembled into an overall algebraic code, and this is assembled with suspicious bit portions 1390 from a preceding decoded output to yield an algebraic code 1350 (i.e., the suspicious bits from a preceding decoded output and the corresponding protected portion parity carried by the currently processing codeword). Algebraic code 1350 is provided to an algebraic decoding circuit 1360 that applies an algebraic decoding algorithm to algebraic code 1350 to yield corrected suspicious bits 1365. the algebraic decoding algorithm reverses the algebraic encoding algorithm described above in relation to FIG. 4.

Further, group algebraic result assembly circuit 1340 passes decoded output 1325 to a suspicious portion identification circuit 1370 as an input 1342. Suspicious portion identification circuit 1370 compares input 1342 to a set of suspicious patterns to yield a partial identification of suspicious patterns maintained in a suspicious portion look up table 1375. Suspicious portion look up table 1375 includes the same bit patterns as suspicious portion look up table 460 of FIG. 4. The result of the comparison of input 1342 to the set of suspicious patterns is provided as suspicious bit portions 1390. Suspicious bit portions 1390 includes suspicious portions across an entire L-group, and is used in relation to user data in a previously processed decoded output.

Turning to FIG. 6, a flow diagram 600 shows a method for protected portion encoding in accordance with various embodiments of the present invention. Following flow diagram 600, a user data set is received (block 605). The received user data set includes information that is to be encoded prior to, for example, transmission or storage. The received user data set is divided into L-groups of N-lengths of data plus one more single data set (block 610). In some cases, the N-lengths of data are equal lengths. In other cases, the lengths are different. In one particular embodiment of the present invention, in the first of the L-groups the N-lengths is a length that when added to generated LDPC parity yields a desired LDPC codeword length. In the other of L-groups, the N-lengths in each are shortened such that they are of a length that when added to both generated LDPC parity and 1/n^{th} of a protected portions segment yields the desired LDPC codeword length. The length of the single data set is such that when added to generated LDPC parity and the protected portions segment yields the desired LDPC codeword length. Such a variable length segmentation results in codewords (user data plus LDPC encoding, and in some cases, the protected portions segment) are the same length.

The first of the L-groups of N-lengths of user data is selected (block 615), and LDPC encoding is applied to each of the N-lengths of user data in the selected group (block 620). This yields N-LDPC codewords for each of the L-groups of N-lengths of user data, and yields a single LDPC codeword for the single data set which are provided (block 625). An example of the resulting encoded codewords for the first L-group that does not include any protection information from a preceding one of the L-groups is shown in FIG. 3b. An example of the resulting encoded codewords for the second and later L-groups that protection information from a preceding one of the L-groups is shown in FIG. 3d. An example of the resulting single encoded codeword corresponding to the single data set including protection information from the last of the L-groups is shown in FIG. 3e. The provided LDPC codewords are the result of the encoding destined for transmission or storage.

It is determined whether the recent LDPC codeword was the last to be encoded (i.e., was the encoded single data set) (block 630). The first of the N-LDPC codewords in the selected one of the L-groups is selected (block 635). The selected N-LDPC codeword is compared to a set of suspicious patterns to yield a partial identification of suspicious patterns (block 640). The aforementioned comparison may be done by accessing a known grouping of suspicious bit patterns from a memory. The suspicious bit patterns are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns. In one particular embodiment of the present invention, the suspicious bit patterns are stored to a memory where the can be accessed for comparison with the group of N-LDPC codewords for identification.

It is determined whether another of the N-LDPC codewords in the selected one of the L-groups remains to be processed (block 645). Where another of the N-LDPC codewords in the selected one of the L-groups remains to be processed (block 645), the next of the N-LDPC codewords is selected (block 655) and the processes of blocks 620-645 are repeated for the newly selected one of the N-LDPC codewords. Alternatively, where no more of the N-LDPC codewords remain for processing (block 645), the N-partial identifications of suspicious patterns generated in block 640 for each of the N-LDPC codewords are aggregated to yield an aggregated suspicious pattern set (block 650). An example of aggregation of the N-partial identifications of suspicious patterns into an aggregated suspicious pattern set is shown in FIG. 3c where identified suspicious bit patterns 311, 312, 313, 314, 315, 316, 317, 318, 319, 320, 321, 322, 323, 324, 325 are aggregated to make protected portions 390.

An algebraic encoding is applied to the aggregated suspicious pattern set to yield an algebraic parity (block 652). FIG. 3c shows an example of encoding the aggregated suspicious pattern set (shown as protected portions 390) is encoded to yield the algebraic parity (shown as protected portion parity 391). The algebraic encoding may be any encoding known in the art. In various embodiments of the present invention, the algebraic encoding algorithm that is applied is specifically chosen to be different from the LDPC encoding algorithm applied in block 620. In some embodiments of the present invention, the algebraic encoding is specifically designed to address the error floor of the LDPC encoding algorithm by protecting suspicious bit patterns likely to negatively impact the error floor of the LDPC encoding algorithm, while leaving the waterfall region of the LDPC encoding algorithm largely unchanged. In one particular embodiment of the present invention, the algebraic encoding algorithm is a weak BCH encoding algorithm as is known in the art. In another particular embodiment of the present invention, the algebraic encoding algorithm is a strong BCH encoding algorithm as is known in the art.

It is determined whether the next data set to be processed is the single data set (block 660) as opposed to one of the L-groups. Where the next data set is the single data set (block 660), the entire algebraic code is added to the single data set (block 675), and the encoding and output processes of blocks 620-625 are performed. An example of such an aggregation is shown in FIG. 3e. Otherwise, where the next data set is not the single data set (block 660), the algebraic code is divided into N-equal portions (block 665). Each of the N-equal portions is added to respective ones of N-lengths of user data in the next data set (block 670). The augmented versions of each of the N-lengths of user data for the one of the L-groups is processed using the encoding and output processes of blocks 620-625 are performed. An example of such an aggregation is shown in FIG. 3d.

Turning to FIG. 7, a flow diagram 700 shows a method for protected portion decoding in accordance with some embodiments of the present invention. Following flow diagram 700, a data set is received from the central memory (block 705). The data set includes protected portion codewords that may be similar to that discussed above in relation to FIG. 3b, 3d or 3e. It is determined whether the received protected portion codewords include the single data set (block 710). The single data set is similar to that described above in relation to FIG. 3e. The non-single data sets are the other multi-segment data sets described in relation to FIG. 3b or 3d.

Where it is determined that the data that was received is not the single data set (block 710), LDPC data decoding is applied to the received data set corresponding to the group of N-LDPC codewords to yield a corresponding group of N-decoded outputs (block 720). Alternatively, where it is determined that the data that was received is the single data set (block 710), the LDPC decoding algorithm is applied to the single data set to yield a singled decoded output (block 725). It is determined whether the application of the LDPC data decoding resulted in a converged codeword (i.e., all errors are corrected)(block 730). Where the resulting LDPC codeword converged (block 730), then it is possible to recover corrected suspicious bits that may be useful for recovering data from a preceding codeword. In particular, it is determined whether the currently processing data corresponds to an initial one of the L-groups of N-lengths (block 735). Where it is the initial group (block 735), no encoded suspicious bit information is included, and as such the converged output is provided (block 775).

Otherwise, where the currently processing data set is not the initial one of the L-groups of N-lengths (block 735), the decoded output includes suspicious bit information that can be used for decoding another of the L-groups of N-lengths. In particular, the portions of the algebraic code (i.e., the protected portions) are accessed from the resulting decoded output and assembled into an algebraic code (block 760). This process is the reverse of that shown in FIGS. 3d and 3e where protected portion parity 391 is re-assembled from the N-portions of protected portion parity 391 (i.e., 340, 341, 342); or protected portion parity 391 is accessed as a whole block from the decoded output.

In addition, the suspicious bit patterns within the decoded output of the previously processed decoded output (i.e., the decoded output to which protected portions 390 correspond, not the decoded output that included the protected portion parity 391) are identified (block 765). This identification process is done using the same comparison process with known suspicious bit patterns that was discussed above in relation to FIGS. 3a-3e. The assembled portions of the algebraic code (block 760) are combined with the suspicious bit patterns from the other groups of codewords (block 765) and algebraic decoding is applied to the combined result to yield corrected suspicious bits for the other group of codewords (block 770). In addition, the decoded outputs corresponding to the group carrying the suspicious bits corresponding to the corrected suspicious bits are modified to include the corrected suspicious bits in place of the original suspicious bits. In some cases, this includes accessing the preceding decoded output from the central memory and overwriting the suspicious bits with the corrected suspicious bits. The converged output is provided (block 775).

Alternatively, where the resulting LDPC codeword failed to converge (block 730), it is determined whether another local iteration is allowed (block 740). Where another local iteration is allowed (block 740), the current group of decoded outputs is provided as feedback to guide the next local iteration of the data decode algorithm (block 755). Alternatively, where another local iteration is not allowed (block 740), the current group of decoded outputs is provided to the central memory to await a subsequent global iteration (block 750).

It should be noted that the approach of reducing the user data to accommodate the addition of protected portions results in a coding rate penalty (i.e., a reduction in the amount of user data relative to parity). In particular, the number of protection bits added to each LDPC codeword is calculated in accordance with the following equation:

$$Augmented User Data - Actual User Data = \frac{Npalg ( 1 + L )}{N ⋆ L + 1} .$$

As an example, assuming Npalg is 384 bits, L is 20 groups, and N is 28 lengths, then on average each LDPC codeword incorporates a fourteen bit additional protection portion. Where for example, each LDPC codeword includes a total of 2,308 bits, the reduction of user data by the fourteen bit additional protection portion represents a small percentage of the overall payload. Some embodiments of the present invention eliminate this payload penalty by puncturing the LDPC parity included in each LDPC codeword.

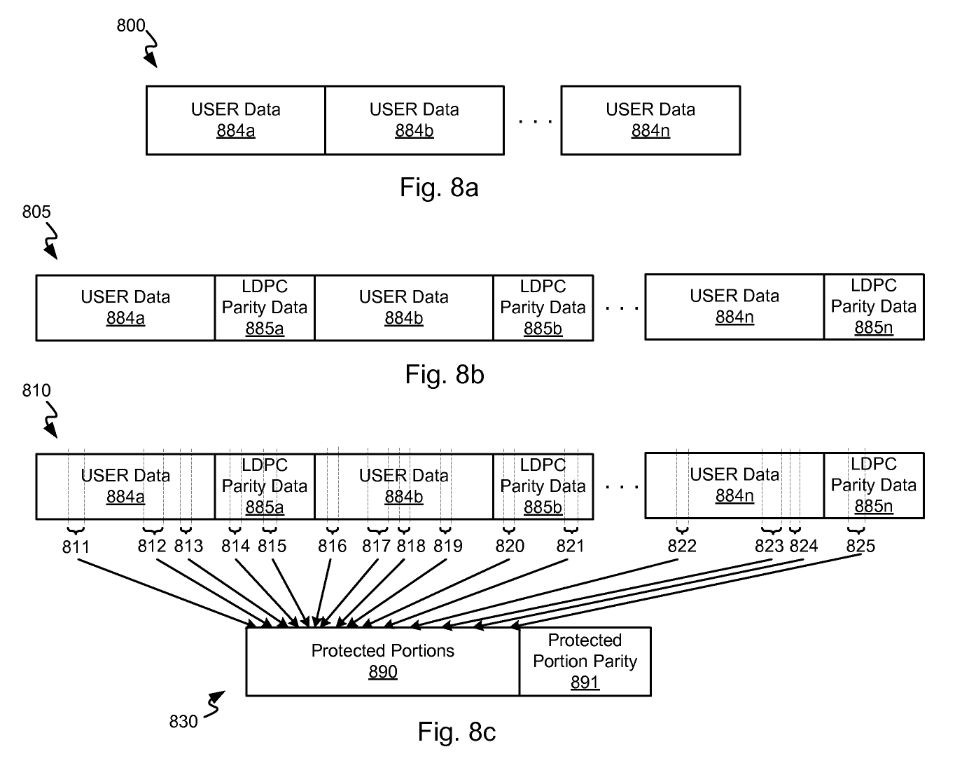

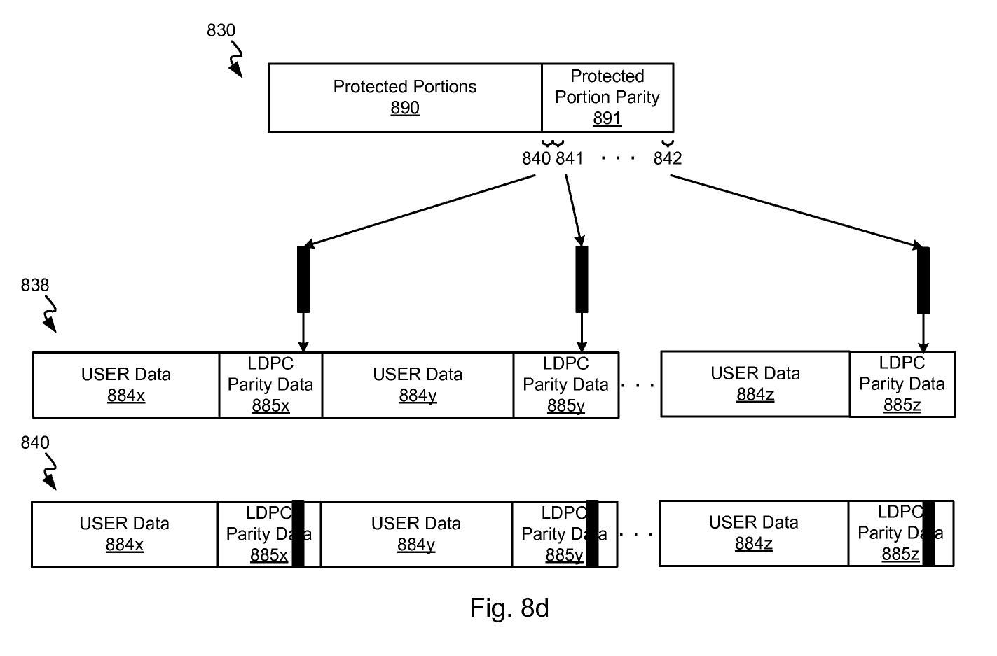

Turning to FIGS. 8a-8d, a process for protected portion encoding transferred using puncture is shown in accordance with some embodiments of the present invention. Turning to FIG. 8a, a graphical representation 800 shows a data set divided into a number of user data portions 884a, 884b, 884n. In some embodiments of the present invention, the data set is divided into L-groups plus one single set, where each of the L-groups includes N-user data portions. In such an embodiment, graphical representation 800 represents one of the L-groups of N-user data portions.

Turning to FIG. 8b, a graphical representation 805 shows a number of LDPC codewords that result from applying an LDPC encoding to each of user data portions 884a, 884b, 884n for a given one of the L-groups. The codewords each include a user data portion and corresponding LDPC parity data. In particular, one LDPC codeword includes user data portion 884a and LDPC parity data 885a, another LDPC codeword includes user data portion 884b and LDPC parity data 885b, and another LDPC codeword includes user data portion 884n and LDPC parity data 885n.

Turning to FIG. 8c, after the encoding discussed in relation to FIG. 8b, suspicious bit patterns are identified in the resulting N-LDPC codewords as shown in a graphical representation 810. In particular, identified suspicious bit patterns 811, 812, 813, 814, 815, 816, 817, 818, 819, 820, 821, 822, 823, 824, 825 are identified. The suspicious bit patterns are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns. In one particular embodiment of the present invention, the suspicious bit patterns are stored to a memory where the can be accessed for comparison with the group of N-LDPC codewords for identification.

Identified suspicious bit patterns 811, 812, 813, 814, 815, 816, 817, 818, 819, 820, 821, 822, 823, 824, 825 are aggregated to yield a protected portions segment 890. A secondary encoding is applied to protected portions segment 890 to yield a protected portion parity 891. Of note, identified suspicious bit patterns 811, 812, 813, 814, 815, 816, 817, 818, 819, 820, 821, 822, 823, 824, 825 may come from either user data portions, LDPC parity bits, or a combination of both. Further, more suspicious bit patterns may be derived from one of the N-LDPC codewords than from another of the N-LDPC codewords. Any encoding algorithm known in the art that is capable of generating encoded data based upon a data input may be used to apply the secondary encoding. In some embodiments of the present invention, the secondary encoding is a non-LDPC encoding. In particular embodiments of the present invention, the secondary encoding is an algebraic encoding. Based upon the disclosure provided herein, one of ordinary skill in the art will recognize a variety of encoding algorithms that may be used to perform the secondary encoding.

Protected portion parity 891 is incorporated into the next group of the L-groups. Thus, the first of the L-groups does not receive any protected parity portion 891. The protected parity portion 891 generated based upon suspicious bit patterns in the first if the L-groups is incorporated into the second of the L-groups. Similarly, the protected parity portion 891 generated based upon suspicious bit patterns in the second if the L-groups is incorporated into the third of the L-groups. This continues until the one single set receives the protected parity portion 891 for the last of the L-groups. Identification of suspicious bit patterns is not performed on the one single set.

Turning to FIG. 8d, a graphical representation 840 shows where each of the N-user data portions for the group is placed in relation to previously encoded LDPC codewords 838, and the N-user data portions are used to puncture the LDPC parity data 840 by overwriting the LDPC parity data. Each of the parity portions 840, 841, 842 of the protected parity portion 891 from the preceding one of the L-groups. As shown, parity portions 840, 841, 842 are used to overwrite a portion of the respective LDPC parity data 885x, 885y, 885z. This avoids consuming user data bits to carry the protected portions. The LDPC parity bits that are overwritten are erased (the soft data is set to a low value indicating a likelihood that they were not properly detected, and are thus likely to me modified by application of the data decoding algorithm.

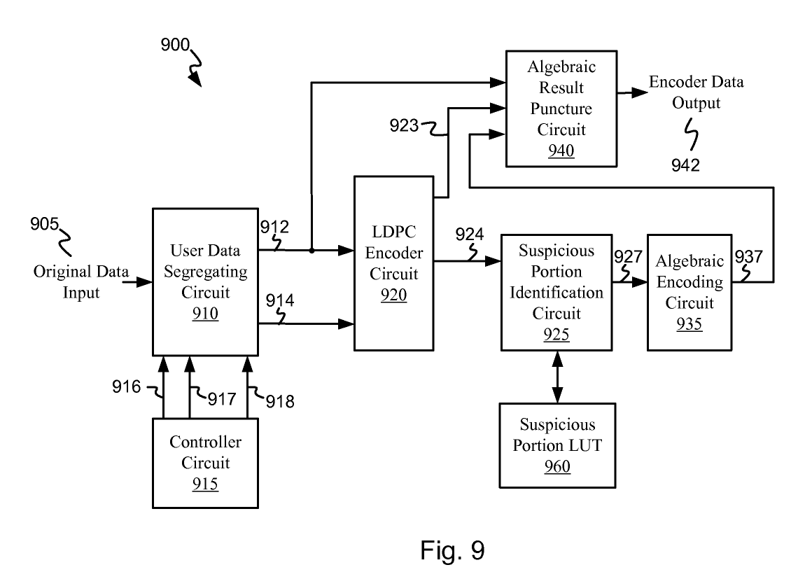

Turning to FIG. 9, a data encoding circuit 900 transporting protected portion encoding via puncture is depicted in accordance with various embodiments of the present invention. Data encoding circuit 900 includes a user data segregating circuit 910 that receives an original data input 905, and segregates the received data into L-groups of N-lengths of data plus one more single data set. Controller circuit 915 is operable to provide a status signal 916 indicating a first of the L-groups, a status signal 917 indicating the other of the L-groups, and a status signal 918 indicating the single data set. All of the N-lengths for each of the L-groups are the same. However, the single data set is of a length that when added to generated LDPC parity and the protected portions segment yields the desired LDPC codeword length.

User data segregating circuit 910 provides the L-groups of N-lengths of data plus one more single data set as a data output 912. A status output 914 indicates whether the data provided as data output 912 is in the first of the L-groups, the other of the L-groups, or the single data set. Data output 912 is provided to both an LDPC encoder circuit 920 and an algebraic result puncture circuit 940. When status output 914 indicates that data output 912 is the first of the L-groups of N-lengths, LDPC encoder circuit 920 applies a low density parity check encoding algorithm to each of the N-lengths of data in the first of the L-groups. Application of the a low density parity check encoding algorithm results in N-LDPC codewords 924, with each of the N-LDPC codewords 924 corresponding to a respective one of the N-lengths of data received as data output 912.

The N-LDPC codewords 924 are provided to a suspicious portion identification circuit 925. Suspicious portion identification circuit 925 compares the N-LDPC codewords 924 to a set of suspicious patterns to yield a partial identification of suspicious patterns maintained in a suspicious portion look up table 960. The result of the comparison of the N-LDPC codewords 924 to the set of suspicious patterns is provided as an aggregated suspicious portion output 927.

Aggregated suspicious portion output 927 includes suspicious portions across an entire L-group. An example of an aggregated suspicious portion output 927 (shown as protected portions 890) is shown in FIG. 8c where a number of identified suspicious bit patterns 811, 812, 813, 814, 815, 816, 817, 818, 819, 820, 821, 822, 823, 824, 825 are aggregated.

The suspicious patterns maintained in suspicious portion look up table 960 are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns.

Aggregated suspicious portion output 927 is provided to an algebraic encoding circuit 935 that applies an algebraic encoding algorithm to the received input to yield protected portion parity data 937. FIG. 8c shows an example of encoding the aggregated suspicious pattern set (shown as protected portions 890) is encoded to yield protected portion parity data 937 (shown as protected portion parity 891). The algebraic encoding may be any encoding known in the art. In various embodiments of the present invention, the algebraic encoding algorithm that is applied is specifically chosen to be different from the LDPC encoding algorithm applied by LDPC encoder circuit 920. In some embodiments of the present invention, the algebraic encoding is specifically designed to address the error floor of the LDPC encoding algorithm by protecting suspicious bit patterns likely to negatively impact the error floor of the LDPC encoding algorithm, while leaving the waterfall region of the LDPC encoding algorithm largely unchanged. In one particular embodiment of the present invention, the algebraic encoding algorithm is a weak BCH encoding algorithm as is known in the art. In another particular embodiment of the present invention, the algebraic encoding algorithm is a strong BCH encoding algorithm as is known in the art.

Protected portion parity data 937 is provided to an algebraic result insertion circuit 940. Algebraic result insertion circuit 940 receives a status indicator 923 from LDPC encoder circuit 920 indicating whether the next data set to be encoded is one of the L-groups of data or the single data set. Where status indicator 923 indicates that the next data set to be encoded is one of the L-groups of data, algebraic result insertion circuit 940 divides protected portion parity data 937 into N-equal parts, and the N-equal parts for the current group of LDPC codewords are overwritten into the LDPC parity bits of the subsequent group of LDPC codewords or the entirely of the protected portion parity 937 is appended to the single LDPC codeword each provided as an output 923. Once the protected portion parity data 937 is added, the results is provided as an encoder data output 942.

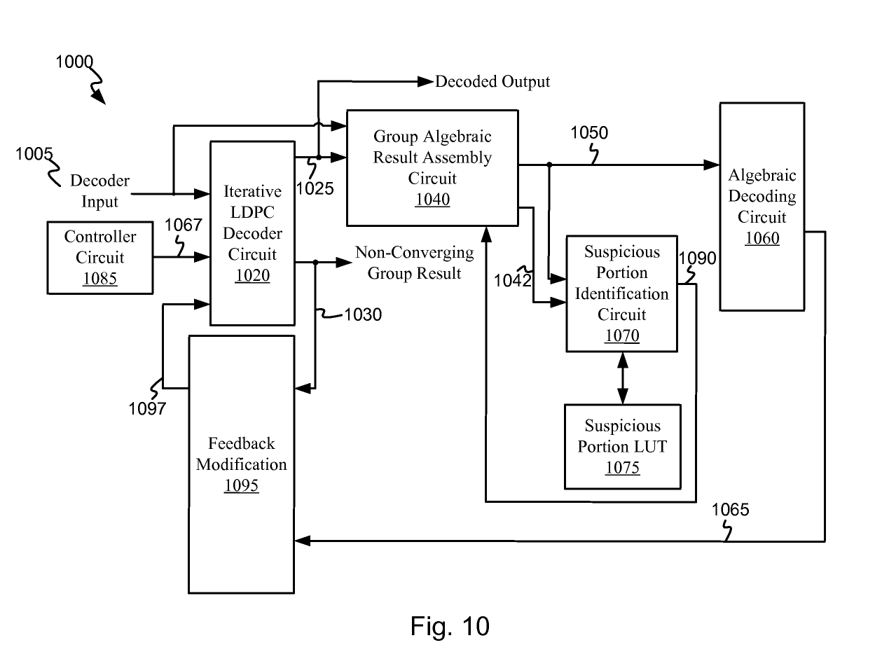

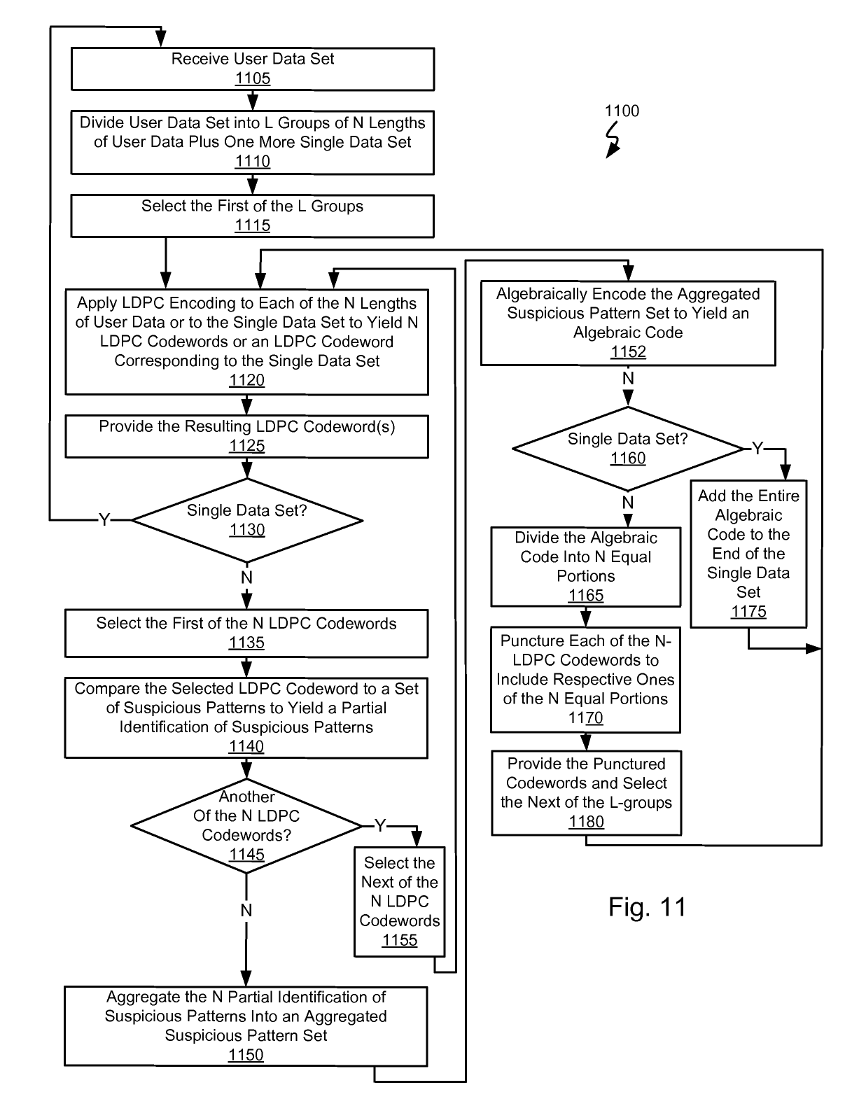

Turning to FIG. 10, a protected portion data decoding circuit 1000 is shown in accordance with various embodiments of the present invention. Protected portion data decoding circuit 1000 may be use in place of protected portion data decoding circuit 570 discussed above in relation to FIG. 5a. Protected portion data decoding circuit 1000 includes an iterative LDPC decoder circuit 1020 that applies a low density parity check decoding algorithm (i.e., the reverse of the low density parity check encoding described above in relation to FIG. 9) guided by an erasure pointer 1067 and, when available, a modified feedback 1097 to yield a decoding result. When erasure pointer 1067 is asserted, soft data associated with a bit or symbol in decoder input 1005 is set to a low value indicating the likelihood that the corresponding bits in decoder input 1005 were incorrectly detected. A controller circuit 1085 asserts erasure pointer 1067 when the bit values corresponding to punctured portions of the received LDPC codewords are introduced to iterative LDPC decoder circuit 1020. By doing this, the probability that iterative LDPC decoder circuit 1020 will change the bit values associated with the erasure pointer is increased. Where the decoding result converges (i.e., all errors are corrected), the decoding result is provided as a decoded output 1025. Alternatively, where the decoding result fails to converge (i.e., not all errors are corrected), the decoding result is provided as a non-converging group result 1030 that may be fed back to guide later local iterations of iterative LDPC decoder circuit 1020.

In addition, decoded output 1025 is provided to a group algebraic result assembly circuit 1040. Group algebraic result assembly circuit 1040 accesses the portions of the algebraic code (i.e., the protected portions) included in decoder input 1005. Where one of the L-groups of N-codewords is being processed, the protected portions can be accessed by reading the punctured portion of the LDPC parity data (i.e., the data that was overwritten with the protected portion information). Alternatively, where the codeword corresponding to the single codeword is received, the protected portions are accessed from the user data of decoded output 1025. Group algebraic result assembly circuit 1040 provides the protected portions are assembled into an overall algebraic code, and this is assembled with suspicious bit portions 1090 from a preceding decoded output to yield an algebraic code 1050 (i.e., the suspicious bits from a preceding decoded output and the corresponding protected portion parity carried by the currently processing codeword). Algebraic code 1050 is provided to an algebraic decoding circuit 1060 that applies an algebraic decoding algorithm to algebraic code 1050 to yield corrected suspicious bits 1065. The algebraic decoding algorithm reverses the algebraic encoding algorithm described above in relation to FIG. 9. Corrected suspicious bits 1065 are provided to a feedback modification circuit 1095 that is operable to modify non-converging group result 1030 to the corrected value. The modified version of non-converging group result 1030 is provided as a modified feedback 1097.

Further, group algebraic result assembly circuit 1040 passes decoded output 1025 to a suspicious portion identification circuit 1070 as an input 1042. Suspicious portion identification circuit 1070 compares input 1042 to a set of suspicious patterns to yield a partial identification of suspicious patterns maintained in a suspicious portion look up table 1075. Suspicious portion look up table 1075 includes the same bit patterns as suspicious portion look up table 960 of FIG. 9. The result of the comparison of input 1042 to the set of suspicious patterns is provided as suspicious bit portions 1090. Suspicious bit portions 1090 includes suspicious portions across an entire L-group, and is used in relation to user data in a previously processed decoded output.

Turning to FIG. 11, a flow diagram 1100 shows a method for puncture transported protected portion encoding in accordance with various embodiments of the present invention. Following flow diagram 1100, a user data set is received (block 1105). The received user data set includes information that is to be encoded prior to, for example, transmission or storage. The received user data set is divided into L-groups of N-lengths of data plus one more single data set (block 1110). The N-lengths are the same for all of the L-groups, but the single data set is of a length that when added to generated LDPC parity and the protected portions segment yields the desired LDPC codeword length.

The first of the L-groups of N-lengths of user data is selected (block 1115), and LDPC encoding is applied to each of the N-lengths of user data in the selected group (block 1120). This yields N-LDPC codewords for each of the L-groups of N-lengths of user data, and yields a single LDPC codeword for the single data set which are provided (block 1125). An example of the resulting encoded codewords for the first L-group that does not include any protection information from a preceding one of the L-groups is shown in FIG. 8b. An example of the resulting encoded codewords for the second and later L-groups that protection information from a preceding one of the L-groups is shown in FIG. 8d. An example of the resulting single encoded codeword corresponding to the single data set including protection information from the last of the L-groups is shown in FIG. 3e. The provided LDPC codewords are the result of the encoding destined for transmission or storage.

It is determined whether the recent LDPC codeword was the last to be encoded (i.e., was the encoded single data set) (block 1130). The first of the N-LDPC codewords in the selected one of the L-groups is selected (block 1135). The selected N-LDPC codeword is compared to a set of suspicious patterns to yield a partial identification of suspicious patterns (block 1140). The aforementioned comparison may be done by accessing a known grouping of suspicious bit patterns from a memory. The suspicious bit patterns are symbols or other sets of bits that have an increased likelihood of causing failure of the LDPC decoding algorithm. In one particular embodiment of the present invention, the number of suspicious bit patterns is limited to 1/9th of the total number of bits included in the group of N-LDPC codewords. Based upon the disclosure provided herein, one of ordinary skill in the art will recognize other amounts of data that may be identified as suspicious bit patterns. As just one example, suspicious bit patterns may include bit patterns identified as trapping sets in bench simulation. Such suspicious bit patterns can be a subset of a trapping set or an intersection of trapping sets. As another example, suspicious bit patterns may include any relatively small group of bits (e.g., ten or fewer bits) that code analysis tools identify as problematic, or bit patterns that exhibit a high error rate compared with most other bit patterns (e.g., the LDPC parity portion of a trunk boundary), or any user defined suspicious bits. Based upon the disclosure provided herein, one of ordinary skill in the art will recognize other bit patterns that may be identified as suspicious bit patterns. In one particular embodiment of the present invention, the suspicious bit patterns are stored to a memory where the can be accessed for comparison with the group of N-LDPC codewords for identification.

It is determined whether another of the N-LDPC codewords in the selected one of the L-groups remains to be processed (block 1145). Where another of the N-LDPC codewords in the selected one of the L-groups remains to be processed (block 1145), the next of the N-LDPC codewords is selected (block 1155) and the processes of blocks 1120-645 are repeated for the newly selected one of the N-LDPC codewords. Alternatively, where no more of the N-LDPC codewords remain for processing (block 1145), the N-partial identifications of suspicious patterns generated in block 1140 for each of the N-LDPC codewords are aggregated to yield an aggregated suspicious pattern set (block 1150). An example of aggregation of the N-partial identifications of suspicious patterns into an aggregated suspicious pattern set is shown in FIG. 8c where identified suspicious bit patterns 811, 812, 813, 814, 815, 816, 817, 818, 819, 820, 821, 822, 823, 824, 825 are aggregated to make protected portions 890.

An algebraic encoding is applied to the aggregated suspicious pattern set to yield an algebraic parity (block 1152). FIG. 8c shows an example of encoding the aggregated suspicious pattern set (shown as protected portions 890) is encoded to yield the algebraic parity (shown as protected portion parity 891). The algebraic encoding may be any encoding known in the art. In various embodiments of the present invention, the algebraic encoding algorithm that is applied is specifically chosen to be different from the LDPC encoding algorithm applied in block 1120. In some embodiments of the present invention, the algebraic encoding is specifically designed to address the error floor of the LDPC encoding algorithm by protecting suspicious bit patterns likely to negatively impact the error floor of the LDPC encoding algorithm, while leaving the waterfall region of the LDPC encoding algorithm largely unchanged. In one particular embodiment of the present invention, the algebraic encoding algorithm is a weak BCH encoding algorithm as is known in the art. In another particular embodiment of the present invention, the algebraic encoding algorithm is a strong BCH encoding algorithm as is known in the art.

It is determined whether the next data set to be processed is the single data set (block 1160) as opposed to one of the L-groups. Where the next data set is the single data set (block 1160), the entire algebraic code is added to the single data set (block 1175), and the encoding and output processes of blocks 1120-1125 are performed. Otherwise, where the next data set is not the single data set (block 1160), the algebraic code is divided into N-equal portions (block 1165). Each of the N-equal portions is stored over the next resulting LDPC codeword (i.e., the LDPC codewords are punctured) for respective ones of N-lengths of user data in the next data set (block 1170). The punctured versions of each of the N-lengths of user data are then provided and the next of the L-groups is selected for processing (block 1180).

Turning to FIG. 12, a flow diagram 1200 shows a method for puncture transported protected portion decoding in accordance with some embodiments of the present invention. Following flow diagram 1200, a data set is received from the central memory (block 1205). The data set includes protected portion codewords that may be similar to that discussed above in relation to FIG. 8b, 8d or 3e. It is determined whether the received protected portion codewords include the single data set (block 1210). The single data set is similar to that described above in relation to FIG. 3e. The non-single data sets are the other multi-segment data sets described in relation to FIG. 8b or 8d.

Where it is determined that the data that was received is not the single data set (block 1210), then the protected parity portion was overwritten into the LDPC parity data and can be accessed and re-assembled to yield the algebraic code (e.g., protected parity portion 891 of FIG. 8c)(block 1260). In addition, LDPC data decoding is applied to the received data set corresponding to the group of N-LDPC codewords to yield a corresponding group of N-decoded outputs (block 1220). This data decoding includes asserting an erasure at the locations in the data set corresponding to the locations in the LDPC parity where the protected portion parity was overwritten during encoding. When an erasure is asserted, the soft data for the result of the data detection is set equal to a low value, and thereby the likelihood that the data decoder will consider that bit resolved is very low. In this way, application of the data decoding algorithm with recover the LDPC parity data overwritten by the protected portion parity during the encoding process.

Alternatively, where it is determined that the data that was received is the single data set (block 1210), the LDPC decoding algorithm is applied to the single data set to yield a singled decoded output (block 1225). Erasure decoding is not used in this limited case as the protected portion parity is incorporated in the payload of the LDPC codeword similar to that discussed above in relation to FIG. 7. It is determined whether the application of the LDPC data decoding resulted in a converged codeword (i.e., all errors are corrected)(block 1230). Where the resulting LDPC codeword converged (block 1230), then it is possible to recover protected parity portions from the single data set as well. Thus, it is determined whether the received protected portion codewords include the single data set (block 1232). Where it is the single data set (block 1232), then the protected parity portion was stored with the user data of the LDPC codeword (e.g., parity portion 391 of FIG. 3e). This protected parity portion data is accessed and re-assembled to yield the algebraic code (block 1262).

In either case, the suspicious bit patterns within the decoded output of the previously processed decoded output (i.e., the decoded output to which protected portions 890 correspond, not the decoded output that included the protected portion parity 891) are identified (block 1265). This identification process is done using the same comparison process with known suspicious bit patterns that was discussed above in relation to FIGS. 8a-8c. The assembled portions of the algebraic code (block 1260) are combined with the suspicious bit patterns from the other groups of codewords (block 1265) and algebraic decoding is applied to the combined result to yield corrected suspicious bits for the other group of codewords (block 1270). In addition, the decoded outputs corresponding to the group carrying the suspicious bits corresponding to the corrected suspicious bits are modified to include the corrected suspicious bits in place of the original suspicious bits. In some cases, this includes accessing the preceding decoded output from the central memory and overwriting the suspicious bits with the corrected suspicious bits. The converged output is provided (block 1275).

Alternatively, where the resulting LDPC codeword failed to converge (block 1230), it is determined whether another local iteration is allowed (block 1240). Where another local iteration is allowed (block 1240), the current group of decoded outputs is provided as feedback to guide the next local iteration of the data decode algorithm (block 1255). Alternatively, where another local iteration is not allowed (block 1240), the current group of decoded outputs is provided to the central memory to await a subsequent global iteration (block 1250).

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing system, the data processing system comprising:
a data encoder circuit operable to:
receive a data set;
augment the data set to include a first protected parity portion corresponding to a first codeword to yield an augmented data set;
apply a first encoding algorithm to the augmented data set to yield a second codeword; and
apply a second encoding algorithm to a portion of the second codeword to yield second protected parity portion.

2. The data processing system of claim 1, wherein the data set is a first data set and the augmented data set is a second augmented data set; and wherein the encoder circuit is further operable to:
receive a second data set;
augment the second data set to include the second protected parity portion corresponding to the second codeword to yield a second augmented data set;
apply the first encoding algorithm to the second augmented data set to yield a third codeword; and
apply the second encoding algorithm to a portion of the third codeword to yield third protected parity portion.

3. The data processing system of claim 1, wherein the first encoding algorithm is a low density parity check encoding algorithm.

4. The data processing system of claim 1, wherein the second encoding algorithm is an algebraic encoding algorithm.

5. The data processing system of claim 1, wherein the data processing system further comprises:
a data decoding circuit operable to:
apply a first data decoding algorithm to the second codeword to yield a user data portion and the first protected parity portion;
collect data from a user data portion of the first codeword corresponding to the first protected parity portion;
apply a second data decoding algorithm to a combination of the user data portion for the first codeword and the first protected parity portion to yield a corrected bit output; and
correct a bit in the user data portion for the first codeword based upon the corrected bit pattern.

6. The data processing system of claim 1, wherein the second codeword includes a second user data portion and a second protected parity portion, wherein the first codeword includes a first user data portion and a first protected parity portion, and wherein the first user data portion and the second user data portion are the same length.

7. The data processing system of claim 1, wherein the second codeword includes a second user data portion and a second protected parity portion, wherein the first codeword includes a first user data portion and a first protected parity portion, and wherein the first user data portion and the second user data portion are different lengths.

8. The data processing system of claim 1, wherein the second codeword includes a second user data portion and a second protected parity portion, wherein the first codeword includes a first user data portion and a first protected parity portion, and wherein the first protected parity portion and the second protected parity portion are the same length.

9. The data processing system of claim 1, wherein the second codeword includes a second user data portion and a second protected parity portion, wherein the first codeword includes a first user data portion and a first protected parity portion, and wherein the first protected parity portion and the second protected parity portion are different lengths.

10. The data processing system of claim 1, wherein the data processing system is part of a data storage device including a storage medium, and wherein the data set is derived from the storage medium.

11. The data processing system of claim 1, wherein the data processing system is part of a communication device operable to receive information from a data transfer medium, and wherein the data set is derived from the information.

12. The data processing system of claim 1, wherein the data processing system is implemented as part of an integrated circuit.

13. The data processing system of claim 1, wherein the second protected parity portion is encoded data corresponding to problematic user data in the first codeword.

14. A method for data processing, the method comprising:
receiving a data set;
augmenting the data set to include a first protected parity portion corresponding to a first codeword to yield an augmented data set;
applying a first encoding algorithm to the augmented data set to yield a second codeword; and
applying a second encoding algorithm to a portion of the second codeword to yield second protected parity portion.

15. The method of claim 14, wherein the data set is a first data set and the augmented data set is a second augmented data set; the method further comprising:
receiving a second data set;
augmenting the second data set to include the second protected parity portion corresponding to the second codeword to yield a second augmented data set;
applying the first encoding algorithm to the second augmented data set to yield a third codeword; and
applying the second encoding algorithm to a portion of the third codeword to yield third protected parity portion.

16. The method of claim 14, wherein the first encoding algorithm is a low density parity check encoding algorithm.

17. The method of claim 16, wherein the second encoding algorithm is not a low density parity check algorithm.

18. The method of claim 14, the method further comprising:
applying a first data decoding algorithm to the second codeword to yield a user data portion and the first protected parity portion;
collecting data from a user data portion of the first codeword corresponding to the first protected parity portion;
applying a second data decoding algorithm to a combination of the user data portion for the first codeword and the first protected parity portion to yield a corrected bit output; and
correcting a bit in the user data portion for the first codeword based upon the corrected bit pattern.

19. The method of claim 14, wherein the second protected parity portion is encoded data corresponding to problematic user data in the first codeword.

20. A storage device, the storage device comprising:
a storage medium;
a head assembly disposed in relation to the storage medium and operable to store an encoded output to the storage medium;
a read channel circuit including a data encoder circuit operable to:
receive a data set;
augment the data set to include a first protected parity portion corresponding to a first codeword to yield an augmented data set;
apply a first encoding algorithm to the augmented data set to yield a second codeword; and
apply a second encoding algorithm to a portion of the second codeword to yield second protected parity portion.
